(19) United States
(12) Patent Application Publication
(10) Pub. No.: US 2025/0324628 A1
(43) Pub. Date: Oct. 16, 2025

(54) Power Semiconductor Device and Method of Producing a Power Semiconductor Device

(71) Applicant: Infineon Technologies Austria AG, Villach (AT)

(72) Inventors: Erich Griebl, Dorfen (DE); Jana Hänsel, Dresden (DE); Thomas Künzig, Baldham (DE); Christian Philipp Sandow, Haar (DE); Thorsten Arnold, Jesenwang (DE)

(21) Appl. No.: 19/094,137

(22) Filed: Mar. 28, 2025

(30) Foreign Application Priority Data
Apr. 10, 2024 (DE) 102024203282.4

(51) Int. Cl. H10D 12/00; H01L 21/265; H10D 12/01; H10D 62/10

(52) U.S. Cl. CPC H10D 12/461; H01L 21/265; H10D 12/032; H10D 12/415; H10D 62/106; H10D 62/126

(57) ABSTRACT

In a power semiconductor device, a deep semiconductor region is provided in addition to a barrier structure. The barrier structure is spatially separated from a trench structure in an active region and arranged in a transition region between the active region and an edge termination region of the power semiconductor device.

### TECHNICAL FIELD

This specification refers to embodiments of a power semiconductor device and to embodiments of a method of producing a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device. The load current is conducted by means of an active region of the power semiconductor device. The active region is surrounded by an edge termination region, which is terminated by an edge of the chip.

In case of a controllable power semiconductor device, e.g., a transistor, the load current path may be controlled by means of insulated electrodes, commonly referred to as gate electrodes. For example, upon receiving a corresponding control signal, e.g., from a driver unit and via a control terminal of the device, the control electrodes may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Conducting) IGBT is one representative of such devices. In an RC IGBT, a single chip unites an IGBT structure and a diode structure.

It is often a design goal to provide the power semiconductor device with specific characteristics, for example relating to the switching properties, e.g., the associated control of the rate of change of the load current (dI/dt) and/or of the rate of change of the collector/emitter voltage (dV/dt). However, it has been observed that simulated, i.e., predicted dI/dt and dV/dt values can differ significantly from the actual values of the manufactured device. Also, it can be challenging to design the device with both specific dI/dt and dV/dt ranges and other target properties, such as low switching losses and/or low conduction losses.

### SUMMARY

According to an embodiment, a power semiconductor device comprises: an active region surrounded by an edge termination region; a semiconductor body extending in both the active region and the edge termination region and comprising, in the active region, a semiconductor drift region of a first conductivity type; a first load terminal at a first side of the semiconductor body; a second load terminal at a second side of the semiconductor body opposite to the first side, wherein the power semiconductor device is configured to conduct, in the active region, a forward load current between the first load terminal and the second load terminal; in the active region and the edge termination region, a trench structure extending along a vertical direction from the first side towards the second side, wherein the trench structure comprises a plurality of control trenches, each control trench including a control trench electrode configured to control the forward load current; in the active region, a deep semiconductor region of the first conductivity type. The deep semiconductor region exhibits a dopant concentration at least twice as high as the dopant concentration of the semiconductor drift region, a thickness within the range of 10% to 120% of the vertical extension of the trench structure, and is arranged to overlap at least partially, for example by at least by 50% of the thickness of the deep semiconductor region, along the vertical direction, with the control trenches. The device further comprises, spatially separated from the trench structure and arranged in a transition region between the active region and the edge termination region, a barrier structure extending along the vertical direction from the first side towards the second side.

The depth of deep semiconductor region may be defined by the depth where the doping concentration has declined to 1% of the peak concentration of the deep semiconductor region.

According to another embodiment, a method of producing a power semiconductor device comprises forming the following components: an active region surrounded by an edge termination region; a semiconductor body extending in both the active region and the edge termination region and comprising, in the active region, a semiconductor drift region of a first conductivity type; a first load terminal at a first side of the semiconductor body; a second load terminal at a second side of the semiconductor body opposite to the first side, wherein the power semiconductor device is configured to conduct, in the active region, a forward load current between the first load terminal and the second load terminal; in the active region and the edge termination region, a trench structure extending along a vertical direction from the first side towards the second side, wherein the trench structure comprises a plurality of control trenches, each control trench including a control trench electrode configured to control the forward load current; in the active region, a deep semiconductor region of the first conductivity type. The deep semiconductor region exhibits a dopant concentration at least twice as high as the dopant concentration of the semiconductor drift region, a thickness within the range of 10% to 120% of the vertical extension of the trench structure, and is arranged to overlap at least partially, for example by at least by 50% of the thickness of the deep semiconductor region, along the vertical direction, with the control trenches. The method further comprises forming, spatially separated from the trench structure and arranged in a transition region between the active region and the edge termination region, a barrier structure extending along the vertical direction from the first side towards the second side.

In accordance with embodiments described herein, the barrier structure may be configured to prevent holes accumulated below the deep semiconductor region, e.g., when the device is turned off, from transferring from the active region towards the edge termination region. This prevention of hole transfer may allow for an improved predicted control of the dI/dt characteristics of the power semiconductor device.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a horizontal projection of a power semiconductor device in accordance with one or more embodiments;

FIG. 2 schematically and exemplarily illustrates a vertical cross-section of a power semiconductor device in accordance with one or more embodiments;

FIG. 3 schematically and exemplarily illustrates a horizontal projection of a power semiconductor device in accordance with an example;

FIG. 4(A) schematically and exemplarily illustrates both a horizontal projection and section of a vertical cross-section of a power semiconductor device in accordance with an example;

FIG. 4(B) schematically and exemplarily illustrates both a horizontal projection and section of a vertical cross-section of a power semiconductor device in accordance with one or more embodiments;

FIGS. 5(A)-5(C) schematically and exemplarily illustrate three partial views of a power semiconductor device in accordance with one or more embodiments;

FIGS. 6(A)-6(B) schematically and exemplarily illustrate two partial views of a power semiconductor device in accordance with one or more embodiments;

FIG. 7 schematically and exemplarily illustrates a horizontal projection of a power semiconductor device in accordance with one or more embodiments;

FIG. 8 schematically and exemplarily illustrates a horizontal projection of a power semiconductor device in accordance with one or more embodiments;

FIG. 9 schematically and exemplarily illustrates a horizontal projection of a power semiconductor device in accordance with one or more embodiments;

FIG. 10 schematically and exemplarily illustrates a horizontal projection of a power semiconductor device in accordance with one or more embodiments;

FIGS. 11(A)-11(C) schematically and exemplarily illustrate three partial views of a power semiconductor device in accordance with one or more embodiments;

FIGS. 12(A)-12(C) schematically and exemplarily illustrate three partial views of a power semiconductor device that relate to a method of producing a power semiconductor device in accordance with one or more embodiments;

FIGS. 13(A)-13(C) schematically and exemplarily illustrate three partial views of a power semiconductor device that relate to a method of producing a power semiconductor device in accordance with one or more embodiments;

FIG. 14 schematically and exemplarily illustrates a horizontal projection of a power semiconductor device in accordance with one or more embodiments;

FIG. 15 schematically and exemplarily illustrates a horizontal projection of a power semiconductor device in accordance with one or more embodiments; and

FIG. 16 schematically and exemplarily illustrates a vertical cross-section of a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip, e.g., exhibiting a stripe cell configuration (or a needle cell configuration) and can be configured to be employed as a power component in a low-, medium- and/or high voltage application.

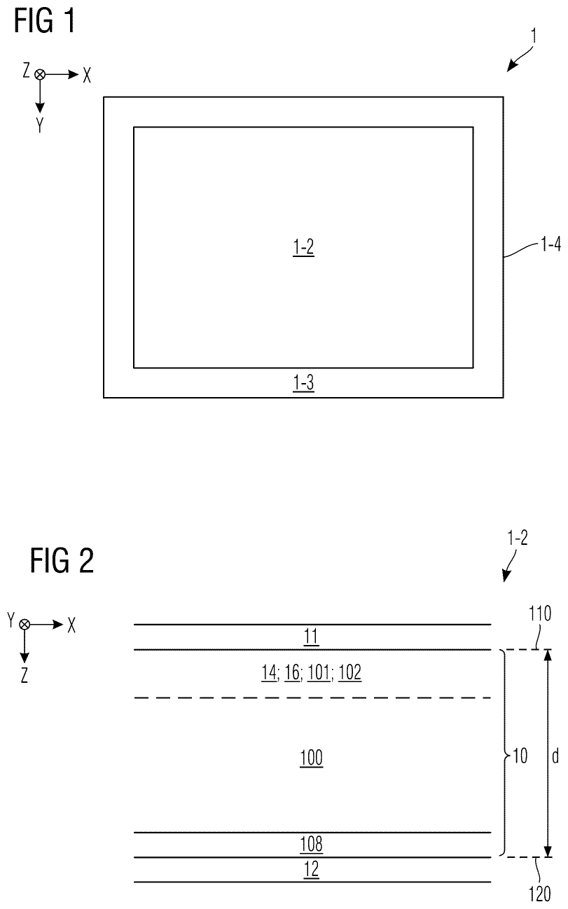

With respect to FIGS. 1, 2 and 15, aspects related to a possible general configuration of the power semiconductor device 1 shall be explained:

The power semiconductor device 1, herein also referred to as “device 1”, comprises, e.g., in a single chip, a semiconductor body 10 configured to conduct a load current, in an active region 1-2, between a first load terminal 11 at a first side 110 of the semiconductor body 10 and a second load terminal 12 at a second side 120 of the semiconductor body 10. The device 1 can be an IGBT (or a derivative thereof, such as RC IGBT). Accordingly, the first load terminal 11 may be an emitter terminal, and the second load terminal 12 may be a collector terminal.

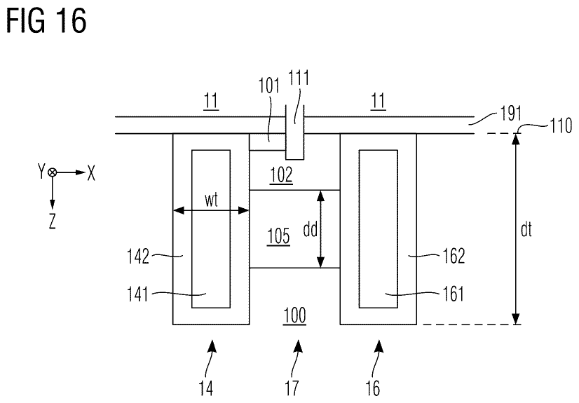

As exemplarily illustrated in FIG. 1, the active region 1-2 of the device 1 is surrounded by an edge termination region 1-3. In the active region 1-2, a trench structure (cf. FIG. 16, reference numerals 14, 16) may form a cell field, which will be explained further below. The edge termination region 1-3 is typically not employed for load current conduction, as it is known to the skilled person. The edge termination region 1-3 is terminated by the chip edge 1-4.

As exemplarily illustrated in FIG. 2, the first side 110 and the second side 120 may be arranged opposite of each other. For example, the first side 110 is a front side of the device 1 and the second side 120 is a back side of the device 1. Accordingly, the device 1 may exhibit a vertical configuration according to which the load current within the device 1 follows a path in parallel to the vertical direction Z. The semiconductor body 10 may be sandwiched between the first load terminal 11 and the second load terminal 12 and exhibit a vertical extension d, e.g., in the range of 50 μm to 700 μm, depending, e.g., on the designated maximal blocking voltage.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities (e.g., said maximal blocking voltage) of the device 1.

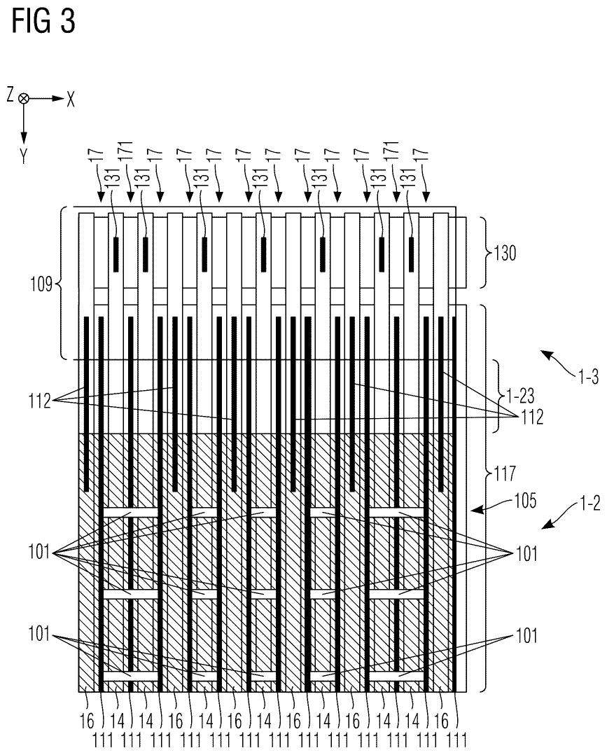

The device 1 further comprises a trench structure 14, 16 that extends from the first side 110 into the semiconductor body 10 towards the second side 120, e.g., along the vertical direction Z. The trench structure will be described in greater detail below. The trench structure 14, 16 comprises at least one trench control electrode 141 (cf. FIG. 3, 16) electrically insulated from the first load terminal 11 and configured to receive a control signal. To this end, the trench control electrode 141 can be electrically connected to a control terminal (not illustrated) of the device 1, in accordance with an embodiment.

As illustrated schematically in FIG. 2 and in more detail in FIG. 16, at the first side 110, the semiconductor body 10 further comprises a semiconductor body region 102 of the second conductivity type electrically connected to the first load terminal 11 and a semiconductor source region 101 of the first conductivity type electrically connected to the first load terminal 11, wherein the semiconductor source region 101 is isolated from the drift region 100 by at least the semiconductor body region 102. The trench control electrode 141 of the trench structure can be configured to induce, upon being subject with a corresponding ON-control signal, an inversion channel in the semiconductor body region 102. This process may set the device 1 into the forward conducting state. The trench control electrode 141 can further be configured to cut off, upon being subject with a corresponding OFF-control signal, said inversion channel in the semiconductor body region 102, which can set the device 1 into the forward blocking state.

A doped region 108 of the semiconductor body 10 below the drift region 100 adjoining the second load terminal 12 at the second side 120 can be configured in accordance with the designated characteristic of the device 1. For example, the doped region 108 can be an emitter region of the second conductivity type, if the device 1 shall exhibit an IGBT configuration. The emitter region is arranged in contact with the second load terminal 12.

In addition, a field stop region (not illustrated) of the first conductivity type can be provided between the drift region 100 and the second load terminal 12, wherein the field stop region exhibits a greater dopant concentration than the drift region 100.

If the device 1 shall exhibit a MOSFET configuration, the emitter region is omitted such that the field stop region (or another highly doped region of the first conductivity type) would adjoin the second load terminal 12. If the device 1 has an RC IGBT configuration, the emitter region may exhibit subsections of the first conductivity type, as it is known to the skilled person.

FIG. 3 schematically and exemplarily illustrates a horizontal projection of the power semiconductor device 1 in accordance with an example. Illustrated is a section of an upper portion of the active region 1-2 (lower part) close to the first side 110, wherein the active region 1-2 adjoins a transition region 1-23 between the active region 1-2 and the edge termination region 1-3, which is also only shown in part. The chip edge 1-4 is not illustrated.

In accordance with the example of FIG. 3, the trench structure, which extends into both the active region 1-2 and the edge termination region 1-3, comprises a plurality of control trenches 14, each control trench 14 including a control trench electrode 141 (cf. FIG. 16) configured to control the forward load current. The trench structure further comprises a plurality of source trenches 16, each source trench 16 including a source trench electrode 161 electrically connected to the first load terminal 11.

The control trenches 14 and the source trenches 16 laterally confine mesas, wherein the mesas comprise first type mesas 17 (cf. also FIG. 16). For example, each first type mesa 17 is laterally confined by at least one of the control trenches 14. Further, each first type mesa 17 can comprise one or more of said semiconductor source regions 101 of the first conductivity type, which is/are electrically connected to the first load terminal 11. Further, each first type mesa 17 can comprise a portion of said semiconductor body region 102 of the second conductivity type, wherein the semiconductor body region 102 isolates the one or more semiconductor source regions 101 from a portion of a region of the first conductivity type, e.g., a portion of the drift region 100 within the first type mesa 17 or a portion of a deep semiconductor region 105, which will be explained in more detail below. The semiconductor body region 102 is electrically connected to the first load terminal 11.

The first type mesas 17 are electrically connected to the first load terminal 11, e.g., as illustrated in FIGS. 3 and 16, e.g., based on first contact plugs 111 that penetrate an insulation layer 191 between the semiconductor body 10 and the first load terminal 11 (or a portion of a load terminal metallization 117 thereof) to establish contact with both the respective semiconductor source region 101 and the respective semiconductor body region 102 within the first type mesa 17.

Each of the control trenches 14 includes a control trench insulator 142 that isolates the control trench electrode 141 from the semiconductor body 10, as schematically illustrated in FIG. 16. Likewise, each of the source trenches 16 includes a source trench insulator 162 that isolates the source trench electrode 161 from the semiconductor body 10.

For example, in the edge termination region 1-3, the device 1 further comprises a control terminal metallization 130, e.g., a gate ring, as illustrated in FIG. 3. that is electrically connected to a control terminal 13 (cf. FIG. 5(C)). For example, third contact plugs 131 extend from the control terminal metallization 130 along the vertical direction Z to contact the control trench electrodes 141 of the control trenches 14 to establish an electrical connection between the control terminal metallization 130 and the control trench electrodes 141. For example, the control trench electrodes 141 receive the control signal via the control terminal metallization 130. The control signal may be generated as a voltage between the control terminal 13 and the first load terminal 11.

The device 1 further comprises, electrically isolated and spatially separated from the control metallization 130, a load terminal metallization 117 that is electrically connected to (or, respectively, that forms a part of) the first load terminal 11. The load terminal metallization 117 may extend into both the active region 1-2 and the transition region 1-23. For example, second contact plugs 112 extend from the load terminal metallization 117 along the vertical direction Z to contact the source trench electrodes 161 of the source trenches 16 to establish the electrical connection between the load terminal metallization 117 and the source trench electrodes 161.

As indicated above, the device 1 furthermore comprises, in the active region 1-2, a deep semiconductor region 105 of the first conductivity type. The deep semiconductor region 105 exhibits a dopant concentration at least twice as high as the dopant concentration of the semiconductor drift region 100. The deep semiconductor region 105 exhibits a thickness dd (cf. FIG. 16) within the range of 10% to 120%, or within the range of 10% to 80%, of the vertical extension dt (cf. FIG. 16) of the trench structure. The deep semiconductor region 105 is arranged to overlap at least partially, for example by at least by 50% of the thickness of the deep semiconductor region 105, along the vertical direction Z, with the control trenches 14, as exemplarily illustrated in FIG. 16. The deep semiconductor region 105 may be arranged in contact with the semiconductor body region 102 or arranged spatially separated, along the vertical direction Z, therefrom. For example, each of the first type mesas 17 includes a portion of the deep semiconductor region 105 that contiguously extends with the respective first type mesa 17, as exemplarily illustrated in FIG. 3 and FIG. 16.

For example, the dopant concentration of the deep semiconductor region 105 varies along the vertical direction Z. For example, the dopant concentration of the deep semiconductor 105 exhibits a maximum at a vertical level which overlaps with the vertical extension of the control trenches 14.

The device 1 may furthermore comprise, in the edge termination region 1-3, a semiconductor well region 109. For example, the semiconductor well region 109 is of the second conductivity type. The semiconductor well region 109 can be electrically connected to the first load terminal 11, e.g., also via a portion of the load terminal metallization 117. The semiconductor well region 109 is spatially separated from the deep semiconductor region 105.

Based on the source trenches 16 and the control trenches 14, a cell field is established in the active region 1-2. Various trench-mesa-patterns may be established. For example, the first type mesas 17 may either be neighbored by two of the control trenches 14 (as the second first type mesa 17 on the left side and the second first type mesa 17 on the right side of FIG. 3, (cf. mesas with reference numeral 171)), or by only one of the control trenches 14 and one of the source trenches 16 (as all the remaining first type mesas 17 in FIG. 3). This aspect will be described in more detail below.

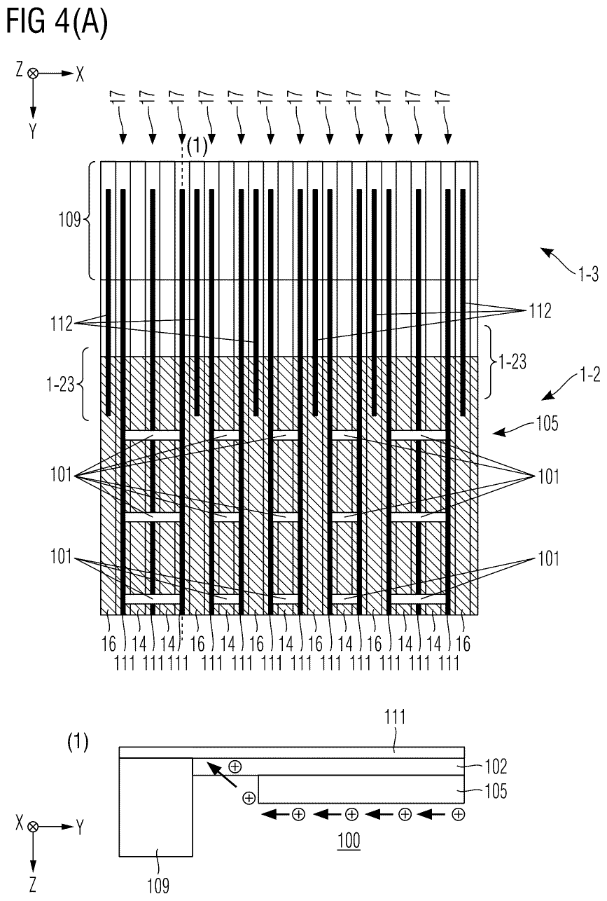

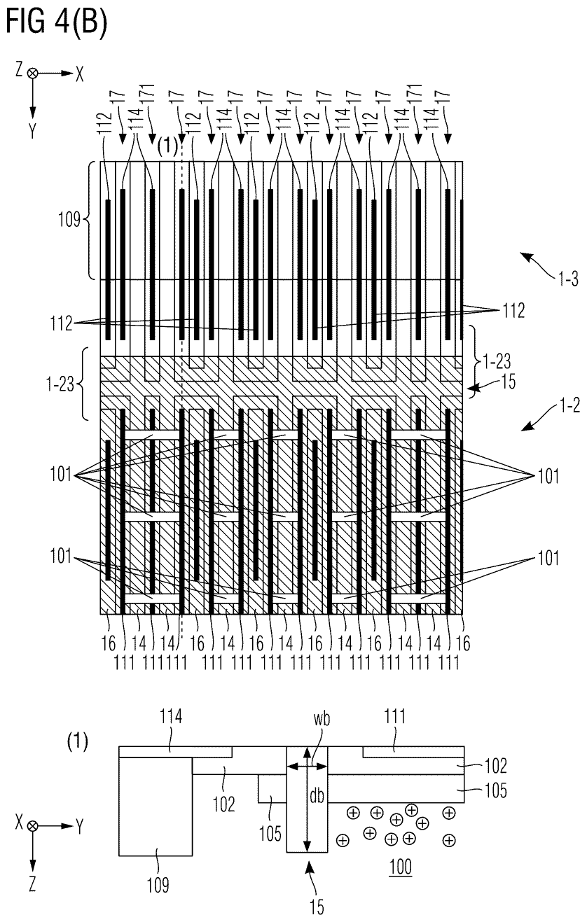

The upper part of FIG. 4(A) is identical to FIG. 3, wherein the load terminal metallization 117 and the control terminal metallization 130 are not illustrated. As illustrated in the lower part of FIG. 4(A), which corresponds to the vertical cross-section at the dashed line (1) in the upper part of FIG. 4(A), in active region 1-2, the deep semiconductor region 105 can be configured to accumulate holes (illustrated as +signs), e.g., during a turn-off process, in the region at or below the deep semiconductor region 105. However, at the periphery of the active region 1-2, the holes may transfer to the transition region 1-23, i.e., towards the well region 109 in the edge termination region 1-3. As the semiconductor body 10 in the edge termination region 1-3 is electrically connected with the first load terminal 11, said holes may accordingly “disappear”. Therefore, said hole accumulation functionality of the deep semiconductor region 105 to keep holes in the region at or below the deep semiconductor region 105 could be limited. This could be disadvantageous because the drain of holes can affect the increase of the voltage at the control electrode 141 during turn-on and accordingly the dI/dt.

In accordance with embodiments described herein and with the exemplary illustrations in FIG. 4(B), the device 1 further comprises, spatially separated from the trench structure 14, 16 and arranged in the transition region 1-23 between the active region 1-2 and the edge termination region 1-3, a barrier structure 15 extending along the vertical direction Z from the first side 110 towards the second side 120.

For example, the barrier structure 15 is configured to avoid transfer of the holes from the active region 1-2 towards the edge termination region 1-3, e.g., during a turn-off process of the device 1 (as illustrated by the lower part of FIG. 4(B).

In an embodiment, the barrier structure 15 extends further along the vertical direction Z than the deep semiconductor region 105.

The upper part of FIG. 4(B) essentially corresponds to the upper part of FIG. 4(A), with the addition of the barrier structure 15 which may imply changes of the configuration of the source trenches 16 and the control trenches 14 in the transition region 1-23. If changes are necessary and how they are implemented can depend on the configuration of the barrier structure 15, some examples of which will be described further below. In accordance with the example illustrated in FIG. 4(B), the barrier structure 15 is embodied as a cross-trench and the control trenches 14 adjoin, both from the edge termination region 1-3 and the active region 1-2, the barrier structure 15, whereas the source trenches 16 terminate spatially distanced from the barrier structure 15.

Before further variants of the barrier structure 15 will be described, some further optional features of the device 1 shall be described below that may be provided for each of the embodiments described herein, if not explicitly stated otherwise.

For example, the trench structure 14, 16 exhibits a trench pattern according to which each trench of the trench structure 14, 16 is either a control trench 14 or a source trench 16. For example, no trench is provided that exhibits a floating trench electrode. As explained above, the first type mesas 17 may either be neighbored by two of the control trenches 14 (as the second first type mesa 171 on the left side and the second first type mesa 171 on the right side of the upper part of FIG. 4(B), in the following referred to as GG-mesas 171), or by only one of the control trenches 14 and one of the source trenches 16 (as all the remaining first type mesas 17 of the upper part of FIG. 4(B), in the following referred to as GS-mesas). For example, the ratio of GS-mesas to GG-mesas is greater than 1, 2, 4 or even larger than 8. Furthermore, second type mesas (not illustrated) may be provided in the active region, wherein each second type mesa is laterally confined by two of the source trenches 16. These second type mesas, in the following referred to as SS-mesas, may or may not be electrically connected to the first load terminal 11. Said exemplary ratios of the GS-mesas to GG-mesas can be provided irrespective of SS-mesas being present or not. In accordance with an embodiment, the variation of the ratio of GS mesas to GG mesas helps to adapt the current slope dI/dt vs. voltage slope dU/dt ratio, e.g., for turn on of the device if the barrier structure 15 is implemented.

The device 1 may further comprise at the first side 110, said control terminal 13 (cf., e.g., FIG. 5(C)) electrically connected with the control trench electrodes 141. The electrical connection between the control terminal 13 and the control trench electrodes 141 is established, e.g., via said third contact plugs 131 and the control terminal metallization 130, in the edge termination region 1-3. The electrical connection between the first load terminal 11 and the source trench electrodes 161 is established in the active region 1-2 (alternatively or additionally in the edge termination region 1-3), e.g., via said second contact plugs 112 and the load terminal metallization 117.

The semiconductor well region 109 is spatially separated from the deep semiconductor region 105, in accordance with an embodiment.

The device 1 described herein can be a bipolar power semiconductor device. For example, the device 1 exhibits an IGBT-configuration (or, respectively, a derivative thereof, such as an RC IGBT-configuration).

For example, as illustrated in the drawings, the cell field in the active region 1-2 has a stripe cell configuration formed by the trench structure 14, 16 and the corresponding first type mesas 17. The barrier structure 15 may exhibit a lateral extension (e.g., along the first lateral direction X) perpendicular to the lateral extension of these stripe cells (e.g., along the second lateral direction Y), i.e., perpendicular to the lateral extension of the control trenches 14 (e.g., along the second lateral direction Y).

In the transition region 1-23, the barrier structure 15 may fill in portions of the first type mesas 17 formed by the trenches of the trench structure 14, 16 in the transition region 1-23, as will be explained in more detail with respect to the drawings. For example, the barrier structure 15 surrounds the active region 1-2 at least partially, e.g., such that at least the first type mesas 17 do not seamlessly adjoin the transition region 1-23, but are interrupted by the barrier structure 15, e.g., such that holes accumulated at or below the deep semiconductor region 105, e.g., during turn-off and/or the following off state of the device 1, cannot escape into the edge termination region 1-3, as explained above.

For example, the barrier structure 15 exhibits a vertical extension db (cf. FIG. 4(B)) within the range of 80% to 200% of the vertical extension dt (cf. FIG. 16) of the trench structure, as indicated above, in an embodiment, the barrier structure 15 extends further along the vertical direction Z than the deep semiconductor region 105.

In an embodiment, the barrier structure 15 exhibits a vertical extension db as deep so as to effectively prevent the hole current flow to the edge termination region 1-3. Said prevention may mean a hole current flow reduction of a factor of at least 103 or of at least 106 compared to a configuration without the barrier structure.

Further, the barrier structure 15 may exhibit a width wb (cf. FIG. 4(B)) within the range of 20% to 1000% of the width wt (cf. FIG. 16) of one of the control trenches 14.

The barrier structure 15 may exhibit an aspect ratio wb/db within the range of 5% to 300%, in accordance with an embodiment.

The barrier structure 15 can be floating (i.e., not electrically connected to a defined electrical potential). For example, barrier structure 15 can alternatively be coupled to a defined electrical potential, e.g., coupled to the electrical potential of the control trench electrodes 141 or to the electrical potential of the first load terminal 11. To this end, the barrier structure 15 may also comprise an electrically conductive material and/or a semi-conductive material.

Furthermore, the barrier structure 15 may extend further along the vertical direction Z than the deep semiconductor region 105. For example, the barrier structure 15 extends up to twice as far along the vertical direction as compared to the trench structure 14, 16.

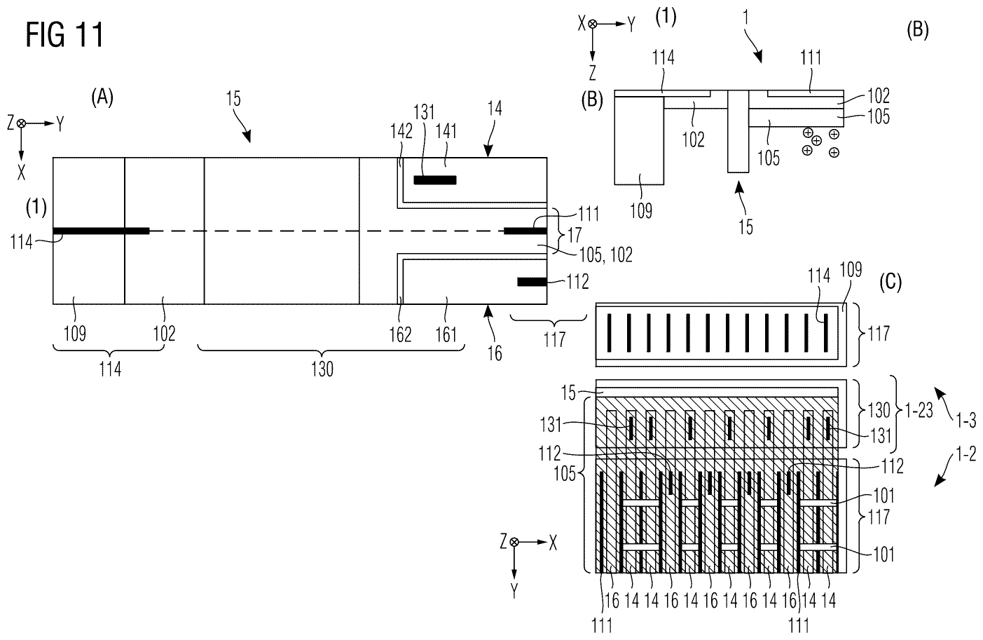

Depending on the position of the deep semiconductor region 105, the barrier structure 15 may penetrate the deep semiconductor region 105 (cf. FIG. 4(B)) or not (cf. FIG. 11(B)). In both cases, the barrier structure 15 may be arranged in contact with the deep semiconductor region 105. Hence, in accordance with an embodiment, the barrier structure 15 is arranged in contact with the deep semiconductor region 105.

In accordance with the embodiment of FIGS. 5(A) to 5(C), the barrier structure 15 is based, in part or entirely, on a semiconductor of the first conductivity type that exhibits a dopant concentration amounting to at least twice of the dopant concentration of the drift region 100. For example, the barrier structure 15 is based, in part or entirely, on a polycrystalline semiconductor material of the first conductivity type. For example, the barrier structure 15 is based, in part or entirely, on a continuously doped crystalline silicon with the same dopant as in the deep semiconductor region 105. Exemplary method steps for producing such versions of the barrier structure 15 will be explained below.

FIG. 5(A) corresponds with FIG. 5(B). FIG. 5(C) illustrates a horizontal projection of the device 1 and FIG. 5(B) an enlarged view of the section (1) indicated in FIG. 5(C). FIG. 5(B) illustrates a variant of the configuration of the edge termination region 1-3, according to which a portion of the load terminal metallization 117 from which fourth contact plugs 114 extend along the vertical direction Z to electrically connect with semiconductor well region 109 of the semiconductor body 10. Spatially separated from said portion of the load terminal metallization 117 is said control terminal metallization 130 from which the third contact plugs 131 extend along the vertical direction Z to electrically connect with the control trench electrodes. Spatially separated from the control terminal metallization 130 is arranged, in the active region 1-2, another portion of the load terminal metallization 117, from which the first contact plugs 111 extend along the vertical direction Z to electrically connect with the first type mesas 17 and from which the second contact plugs 112 extend along the vertical direction Z to electrically connect with the source trench electrodes 161, as already described with respect to FIG. 4(B). In accordance with an embodiment, as illustrated, the control terminal metallization 130 may laterally overlap with the barrier structure 15. Also, an inner portion of the load terminal metallization 117 may laterally overlap with the barrier structure 15. An outer load terminal metallization 125 may exhibit the electrical potential of the second load terminal 12.

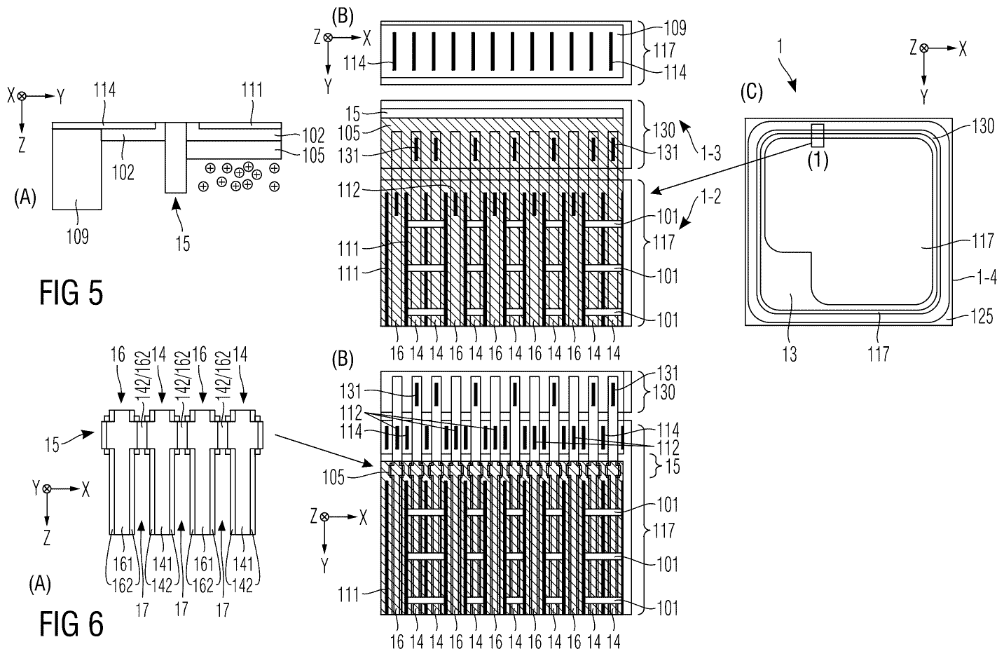

In accordance with the embodiment of FIGS. 6(A) and 6(B), the barrier structure 15 is based in part or entirely, on local widenings of the trenches 14, 16 of the trench structure, as best illustrated in FIG. 6(A). For example, the trenches 14, 16 are locally widened in the transition region 1-23 to get a full oxidation of the trench insulators 142, 162 to fill the respective portions of the first type mesas 17. The relevant description of FIG. 5(B) may likewise apply to FIG. 6(B).

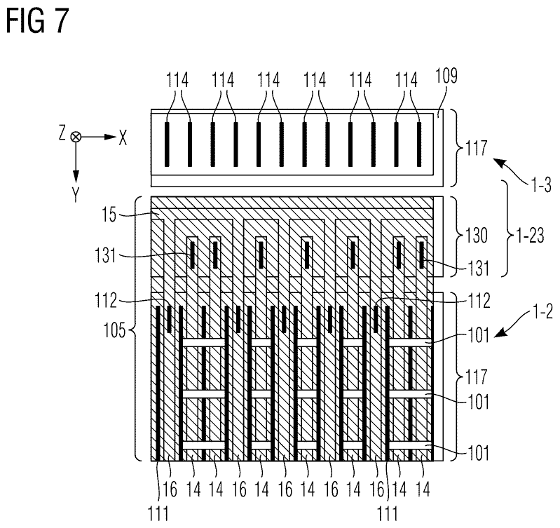

In accordance with the embodiment exemplarily illustrated in FIG. 7, the barrier structure 15 is embodied as a barrier trench. For example, the barrier structure 15 may be configured as a cross-trench and include a (non-illustrated) cross-trench electrode. For example, the cross-trench electrode is electrically connected, e.g., via one of the contact plugs 112, to the first load terminal 11, as the source trench electrodes 161. For example, the source trenches 16 arranged in the active region 1-2 adjoin the barrier structure 15 in the transition region 1-23. For example, in this variant, the source trenches 16 terminate at the barrier structure 15 and do accordingly not extend into the edge termination region 1-3. For example, in the barrier structure 15, the source trench electrodes 161 adjoin the optionally provided and non-illustrated cross-trench electrode of the barrier structure 15.

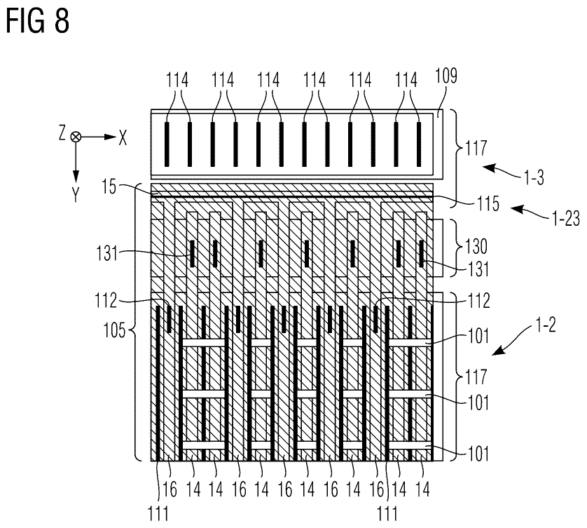

The description of FIG. 7 likewise applies to FIG. 8, the difference being that in accordance with the embodiment exemplarily illustrated in FIG. 8, a fifth contact plug 115 is employed to establish the electrical connection between the optionally provided and non-illustrated cross-trench electrode of the barrier structure 15 and the portion of the load terminal metallization 117 in the transition region 1-23. In this variant, no separate/further electrical connection between said portion of the load terminal metallization 117 and the first load terminal 11 needs to be provided, as this connection is established via the second contact plugs 112 in the active region 1-2, the source trench electrodes 161 that adjoin the optionally provided and non-illustrated cross-trench electrode of the barrier structure 15 and via said firth contact plug 115.

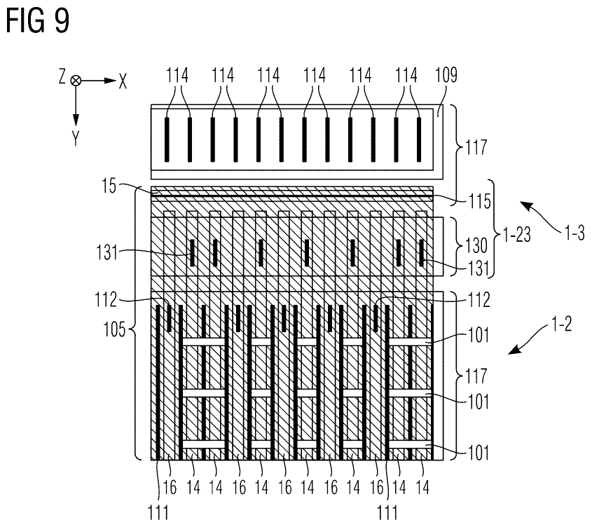

In accordance with FIG. 9, the barrier structure 15 is again embodied as a barrier trench and also, as in FIG. 8, laterally overlaps with the said portion of the load terminal metallization 117 in the transition region 1-23. However, neither the source trenches 16 nor the control trenches 14 adjoin the barrier structure 15. The fifth contact plug 115 is employed to establish the electrical connection between the optionally provided and non-illustrated cross-trench electrode of the barrier structure 15 and said portion of the load terminal metallization 117 in the transition region 1-23. Said portion of the load terminal metallization 117 in the transition region 1-23 can be connected to the first load terminal 11 by other means.

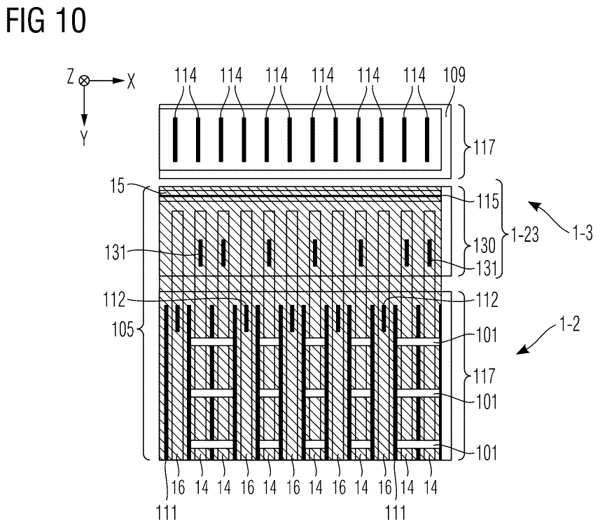

In accordance with FIG. 10, the barrier structure 15 is again embodied as a barrier trench and laterally overlaps with the control terminal metallization 130 in the transition region 1-23. Neither the source trenches 16 nor the control trenches 14 adjoin the barrier structure 15. Rather, the fifth contact plug 115 is employed to establish the electrical connection between the optionally provided and non-illustrated cross-trench electrode of the barrier structure 15 and the control terminal metallization 130 in the transition region 1-23. The upper portion of the load terminal metallization 117 is connected to the first load terminal 11.

In accordance with the embodiment exemplarily illustrated in FIG. 11, the deep semiconductor region 105 terminates at the barrier structure 15. For example, in this case, the barrier structure 15 is based, in part or entirely, on a semiconductor of the first conductivity type that exhibits a dopant concentration amounting to at least twice of the dopant concentration of the drift region 100. For example, the barrier structure 15 is based, in part or entirely, on a polycrystalline semiconductor material of the first conductivity type. For example, the barrier structure 15 is based, in part or entirely, on a continuous doped crystalline silicon with the same or a higher dopant concentration as in the deep semiconductor region 105. FIG. 11(B) illustrates the vertical cross-section along dashed line (1) shown in FIG. 11(A). The barrier structure 15 may laterally overlap with the control terminal metallization 130, as best shown in FIG. 11(C). However, the barrier structure 15 is electrically isolated from the electrical potential of the control terminal metallization 130. For example, the barrier structure 15 is kept floating. For example, the barrier structure 15 surrounds the entire active region 1-2.

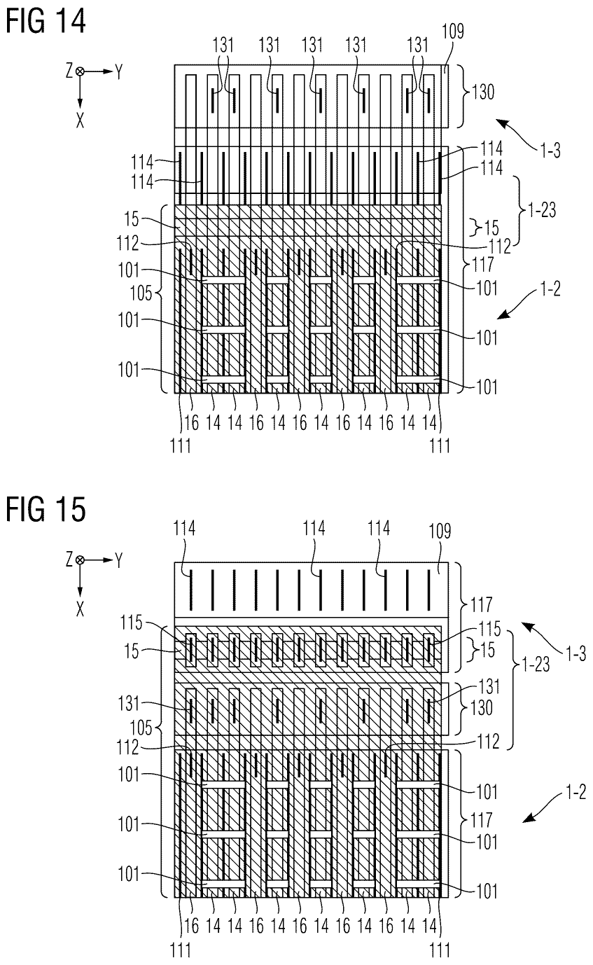

In accordance with the embodiment of FIG. 14, no portion of the load terminal metallization 117 is provided in the edge termination region 1-3. Rather, the load terminal metallization 117 is only provided in the active region 1-2 and the transition region 1-23. The deep semiconductor region 105 is penetrated by the barrier structure 15. Again, the barrier structure 15 may be based, in part or entirely, on a semiconductor of the first conductivity type that exhibits a dopant concentration amounting to at least twice of the dopant concentration of the semiconductor drift region 100. For example, the barrier structure 15 is based, in part or entirely, on a polycrystalline semiconductor material of the first conductivity type. For example, the barrier structure 15 is based, in part or entirely, on a continuously doped crystalline silicon with the same or a higher dopant as in the deep semiconductor region 105.

In accordance with the embodiment of FIG. 15, a portion of the load terminal metallization 117 is provided in the edge termination region 1-3 (and could accordingly be referred to as emitter ring) and extends into the transition region 1-23. The deep semiconductor region 105 is penetrated by the barrier structure 15. Again, the barrier structure 15 may be based, in part or entirely, on a semiconductor of the first conductivity type that exhibits a dopant concentration amounting to at least twice of the dopant concentration of the semiconductor drift region 100. For example, the barrier structure 15 is based, in part or entirely, on a polycrystalline semiconductor material of the first conductivity type. For example, the barrier structure 15 is based, in part or entirely, on a continuously doped crystalline silicon with the same or a higher dopant as in the deep semiconductor region 105. Optionally, the fifth contact plugs 115 can be provided to electrically connect the barrier structure 15 with the portion of the load terminal metallization 117.

Presented herein is also a method of producing a power semiconductor device. For example, the method of producing a power semiconductor device comprises forming the following components: an active region surrounded by an edge termination region; a semiconductor body extending in both the active region and the edge termination region and comprising, in the active region, a semiconductor drift region of a first conductivity type; a first load terminal at a first side of the semiconductor body; a second load terminal at a second side of the semiconductor body opposite to the first side, wherein the power semiconductor device is configured to conduct, in the active region, a forward load current between the first load terminal and the second load terminal; in the active region and the edge termination region, a trench structure extending along a vertical direction from the first side towards the second side, wherein the trench structure comprises a plurality of control trenches, each control trench including a control trench electrode configured to control the forward load current; in the active region, a deep semiconductor region of the first conductivity type. The deep semiconductor region exhibits a dopant concentration at least twice as high as the dopant concentration of the semiconductor drift region, a thickness within the range of 10% to 120% of the vertical extension of the trench structure, and is arranged to overlap at least partially, along the vertical direction, with the control trenches. The method further comprises forming, spatially separated from the trench structure and arranged in a transition region between the active region and the edge termination region, a barrier structure extending along the vertical direction from the first side towards the second side.

Embodiments of the above-described method correspond to the embodiments of the power semiconductor device 1 described above. Accordingly, these embodiments of the method will not literally be described herein, but it is referred to the above.

For example, forming the barrier structure 15 in accordance with the preceding paragraph may include carrying out an implantation processing step, e.g., an angled dual-sidewall implantation.

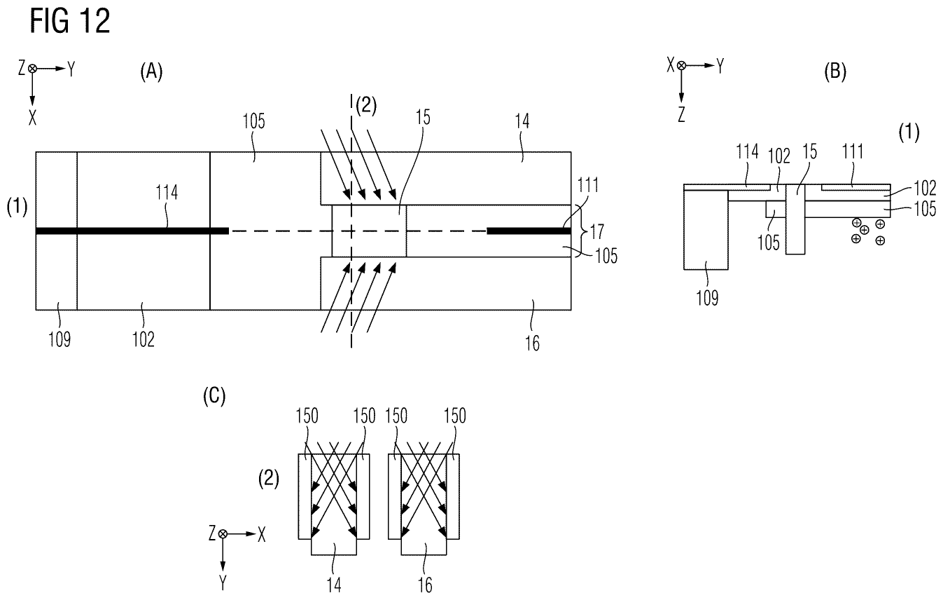

For example, such angled dual-sidewall implantation is schematically illustrated based on FIGS. 12(A)-(C). FIG. 12(A) illustrates a horizontal projection including two dashed lines (1) and (2), wherein corresponding vertical cross-sections are illustrated in FIG. 12(B) (along line (1)) and in FIG. 12(C) (along line (2)).

For example, the barrier structure 15 is formed by masked (e.g., angled) dual mode sidewall implants into the trenches 14 and 16 before the respective trench electrodes 141, 161 are formed. For example, only two small implant areas to the right and left close to trench ends are subjected to such implantation, as illustrated in FIG. 12(C). In order not to implant too deep along the vertical direction, the “shadowing effect” of trench sidewalls can be used, in accordance with an embodiment. Furthermore, the angle of the angled dual-sidewall implantation can be chosen such that the bottom of the trenches is not or at most insignificantly subjected to the implantation, in accordance with an embodiment.

After the implantation, a diffusion processing step can be carried out such that the implanted areas 150 in FIG. 12(C) merge together to form the barrier structure 15. For example, even after the diffusion, the barrier structure 15 does not extend deeper than the trenches 14, 16, in accordance with an embodiment.

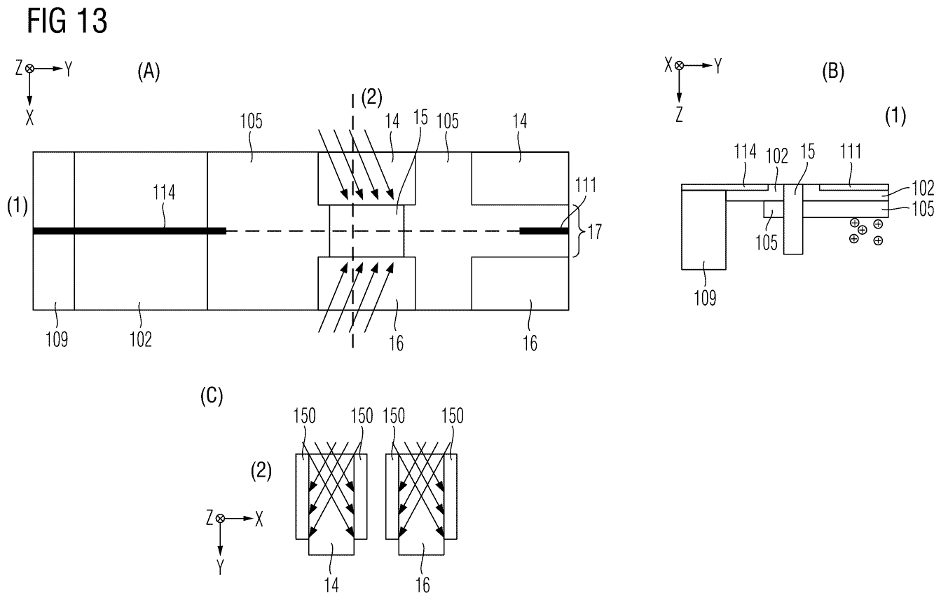

The setup of the FIGS. 13(A) to 13(C), which illustrate a variant of the implantation processing step, corresponds to the setup of the FIGS. 12(A) to 12(C), with the difference that the trenches 14, 16 are interrupted, e.g., such that no uninterrupted accumulation layer is formed at the trench sidewalls at or below deep semiconductor region 105, which may provide for an additional hole confinement. Otherwise, the description with respect to FIGS. 12(A) to 12(C) likewise applies.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor device, comprising:
an active region surrounded by an edge termination region;
a semiconductor body extending in both the active region and the edge termination region and comprising, in the active region, a semiconductor drift region of a first conductivity type;
a first load terminal at a first side of the semiconductor body;
a second load terminal at a second side of the semiconductor body opposite to the first side, wherein the power semiconductor device is configured to conduct, in the active region, a forward load current between the first load terminal and the second load terminal;
in the active region and the edge termination region, a trench structure extending along a vertical direction from the first side towards the second side, wherein the trench structure comprises a plurality of control trenches each including a control trench electrode configured to control the forward load current;
in the active region, a deep semiconductor region of the first conductivity type, wherein the deep semiconductor region
exhibits a dopant concentration at least twice as high as the dopant concentration of the semiconductor drift region,
exhibits a thickness within a range of 10% to 120% of the vertical extension of the trench structure, and
is arranged to overlap at least partially, along the vertical direction (Z), with the control trenches; and
spatially separated from the trench structure and arranged in a transition region between the active region and the edge termination region, a barrier structure extending along the vertical direction from the first side towards the second side.

2. The power semiconductor device of claim 1, wherein the trench structure comprises a plurality of source trenches each including a source trench electrode electrically connected to the first load terminal.

3. The power semiconductor device of claim 2, wherein the trench structure has a trench pattern according to which each trench of the trench structure is either a control trench or a source trench.

4. The power semiconductor device of claim 2, further comprising:
at the first side, a control terminal electrically connected with the control trench electrodes,
wherein the electrical connection between the control terminal and the control trench electrodes is established in the edge termination region,
wherein the electrical connection between the first load terminal and the source trench electrodes is established in the active region.

5. The power semiconductor device of claim 1, further comprising:
a semiconductor well region arranged in the edge termination region, electrically connected to the first load terminal, and spatially separated from the barrier structure.

6. The power semiconductor device of claim 1, wherein the barrier structure has a lateral extension perpendicular to a lateral extension of the control trenches.

7. The power semiconductor device of claim 1, wherein the barrier structure fills in portions of mesas formed by the trenches of the trench structure.

8. The power semiconductor device of claim 1, wherein the barrier structure has a vertical extension within a range of 80% to 120% of the vertical extension of the trench structure.

9. The power semiconductor device of claim 1, wherein the barrier structure has a width within a range of 20% to 200% of a width of one of the control trenches.

10. The power semiconductor device of claim 1, wherein the barrier structure is either electrically floating or coupled to an electrical potential of the control trench electrodes or of the first load terminal.

11. The power semiconductor device of claim 1, wherein the barrier structure extends further along the vertical direction than the deep semiconductor region, and/or wherein the barrier structure is arranged in contact with the deep semiconductor region.

12. The power semiconductor device of claim 1, wherein the barrier structure penetrates the deep semiconductor region.

13. The power semiconductor device of claim 1, wherein the barrier structure surrounds the active region at least partially.

14. The power semiconductor device of claim 1, wherein the barrier structure is based, in part or entirely, on a semiconductor of the first conductivity type that has a dopant concentration amounting to at least twice of a dopant concentration of the semiconductor drift region.

15. The power semiconductor device of claim 1, wherein the barrier structure is based, in part or entirely, on a polycrystalline semiconductor material of the first conductivity type.

16. The power semiconductor device of claim 1, wherein the barrier structure is based, in part or entirely, on a continuously doped crystalline silicon with a same dopant as in the deep semiconductor region.

17. The power semiconductor device of claim 1, wherein the barrier structure is based, in part or entirely, on local widenings of the trenches of the trench structure.

18. The power semiconductor device of claim 1, wherein the trenches of the trench structure laterally confine a plurality of mesas comprising first type mesas, each of which is laterally confined by at least one of the control trenches and comprises:
a portion of the deep semiconductor region;
one or more semiconductor source regions of the first conductivity type and electrically connected to the first load terminal; and
a semiconductor body region of a second conductivity type, wherein the semiconductor body region isolates the one or more semiconductor source regions from a portion of the drift region within the first type mesa or from the portion of the deep semiconductor region.

19. The power semiconductor device of claim 1, wherein the barrier structure is embodied as a barrier trench and/or comprises one or more barrier trenches.

20. The power semiconductor device of claim 1, wherein the power semiconductor device has an IGBT-configuration.

21. A method of producing a power semiconductor device, the method comprising:
forming an active region surrounded by an edge termination region;
forming a semiconductor body extending in both the active region and the edge termination region and comprising, in the active region, a semiconductor drift region of a first conductivity type;
forming a first load terminal at a first side of the semiconductor body;
forming a second load terminal at a second side of the semiconductor body opposite to the first side, wherein the power semiconductor device is configured to conduct, in the active region, a forward load current between the first load terminal and the second load terminal;
in the active region and the edge termination region, forming a trench structure extending along a vertical direction from the first side towards the second side, wherein the trench structure comprises a plurality of control trenches each including a control trench electrode configured to control the forward load current;
in the active region, forming a deep semiconductor region of the first conductivity type, wherein the deep semiconductor region has a dopant concentration at least twice as high as a dopant concentration of the semiconductor drift region, has a thickness within a range of 10% to 120% of the vertical extension of the trench structure, and is arranged to overlap at least partially, along the vertical direction, with the control trenches; and
forming a barrier structure spatially separated from the trench structure and arranged in a transition region between the active region and the edge termination region, the barrier structure extending along the vertical direction from the first side towards the second side.

22. The method of claim 21, wherein forming the barrier structure comprises carrying out an angled dual-sidewall implantation.
